(19) United States
(12) Patent Application Publication
(10) Pub. No.: US 2021/0217962 A1
(43) Pub. Date: Jul. 15, 2021

(54) FIELD EFFECT TRANSISTOR AND METHOD FOR MAKING THE SAME

(71) Applicants: Tsinghua University, Beijing (CN); HON HAI PRECISION INDUSTRY CO., LTD., New Taipei (TW)

(72) Inventors: XIN-HE YANG, Beijing (CN); PENG LIU, Beijing (CN); KAI-LI JIANG, Beijing (CN); SHOU-SHAN FAN, Beijing (CN)

(21) Appl. No.: 17/067,736

(22) Filed: Oct. 11, 2020

(30) Foreign Application Priority Data
Jan. 15, 2020 (CN) 202010044328.9

(51) Int. Cl. H01L 51/00; H01L 51/05

(52) U.S. Cl. CPC H01L 51/0048; H01L 51/0558

(57) ABSTRACT

A field effect transistor comprises a source electrode, a drain electrode, a single carbon nanotube, an insulating layer and a gate electrode. The gate electrode is located on a first surface of the insulating layer. The source electrode and the drain electrode are located on a second surface of the insulating layer and spaced away from each other. The single carbon nanotube comprises a first end, a second end opposite to the first end, and a middle portion located between the first end and the second end. The first end of the single carbon nanotube is electrically connected to the source electrode, and the second end of the single carbon nanotube is electrically connected to the drain electrode. The middle portion of the single carbon nanotube comprises a plurality of defects.

### CROSS-REFERENCE TO RELATED APPLICATIONS

This application claims all benefits accruing under 35 U.S.C. § 119 from China Patent Application No. 202010044328.9, filed on Jan. 15, 2020, in the China National Intellectual Property Administration, the contents of which are hereby incorporated by reference. The application is also related to co-pending applications entitled, “THERMIONIC EMISSION DEVICE AND METHOD FOR MAKING THE SAME”, filed **** (Atty. Docket No. US78627).

### FIELD

The present disclosure relates to a field effect transistor.

### BACKGROUND

A preparation of devices that can work stably in a high-temperature environment is one of the core issues of high-temperature electronics. Conventionally, a wide-bandgap semiconductor, such as gallium nitride or silicon carbide, is used. However, there are a series of difficulties in a preparation of the wide-bandgap semiconductor. So this greatly limits a development of high-temperature electronics.

Carbon nanotubes have excellent electronic properties and can be used to make room temperature field effect transistors and flexible field effect transistors. However, their application in high-temperature electronics has not yet been studied. Moreover, although carbon nanotubes still maintain excellent electrical transport properties at high temperatures, such as a resistivity that is basically constant with temperature and higher mobility at high temperatures, an on-off ratio of the carbon nanotubes is low at the high temperature.

### BRIEF DESCRIPTION OF THE DRAWINGS

Implementations of the present technology will now be described, by way of example only, with reference to the attached figures.

FIG. 1 is a view of the first embodiment of a field effect transistor according to one example.

FIG. 2 is a view of the first embodiment of the field effect transistor according to another embodiment.

FIG. 3 is a flowchart of one embodiment of a method for making the field effect transistor.

FIG. 4 is a view of the second embodiment of the field effect transistor according to one example.

FIG. 5 a view of the second embodiment of the field effect transistor according to another example.

FIG. 6 is a view of the third embodiment of the field effect transistor according to one example.

FIG. 7 a view of the third embodiment of the field effect transistor according to another example.

FIG. 8 is a graph showing a result of a sudden increase in the on-off ratio of a single carbon nanotube due to an increase of a bias voltage at both ends of the single carbon nanotube.

FIG. 9 is a Rayleigh photograph of the single carbon nanotubes with defects formed in the middle portion.

FIG. 10 is a transfer characteristic curve of the single carbon nanotube with defects formed in the middle portion.

FIG. 11 shows an energy band and the transfer characteristic curve at a high temperature of the single carbon nanotube without defects.

FIG. 12 shows the energy band and the transfer characteristic curve at a high temperature of the single carbon nanotube with defects.

FIG. 13 is a diagram of a working principle of the single carbon nanotube with a high on-off ratio.

### DETAILED DESCRIPTION

The disclosure is illustrated by way of example and not by way of limitation in the figures of the accompanying drawings in which like references indicate similar elements. It should be noted that references to “an” or “one” embodiment in this disclosure are not necessarily to the same embodiment, and such references mean “at least one”.

It will be appreciated that for simplicity and clarity of illustration, where appropriate, reference numerals have been repeated among the different figures to indicate corresponding or analogous elements. In addition, numerous specific details are set forth in order to provide a thorough understanding of the embodiments described herein. However, it will be understood by those of ordinary skill in the art that the embodiments described herein can be practiced without these specific details. In other instances, methods, procedures, and components have not been described in detail so as not to obscure the related relevant feature being described. Also, the description is not to be considered as limiting the scope of the embodiments described herein. The drawings are not necessarily to scale, and the proportions of certain parts can be exaggerated to illustrate details and features of the present disclosure better.

Several definitions that apply throughout this disclosure will now be presented.

The term “comprise” or “comprising” when utilized, means “include or including, but not necessarily limited to”; it specifically indicates open-ended inclusion or membership in the so-described combination, group, series, and the like.

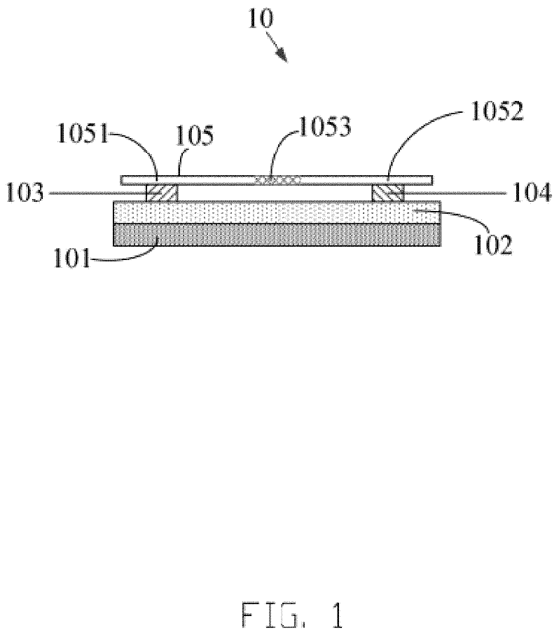

Referring to FIG. 1, a field effect transistor 10 is provided in the first embodiment. The field effect transistor 10 comprises a source electrode 103, a drain electrode 104, a single carbon nanotube 105, an insulating layer 102 and a gate electrode 101. The gate electrode 101 is insulated from the source electrode 103, the drain electrode 104, and the single carbon nanotube 105 through the insulating layer 102. The source electrode 103 and the drain electrode 104 are spaced apart from each other. The single carbon nanotube 105 comprises a first end 1051, a second end 1052 opposite to the first end 1051, and a middle portion 1053 located between the first end 1051 and the second end 1052. The first end 1051 of the single carbon nanotube 105 is electrically connected to the source electrode 103, and the second end 1052 of the single carbon nanotube 105 is electrically connected to the drain electrode 104. The middle portion 1053 comprises a plurality of defects.

The gate electrode 101 can be a free-standing layered structure or a thin film disposed on a surface of an insulating substrate. A thickness of the gate electrode 101 is not limited. In one embodiment, a thickness of the gate electrode 101 is ranged from about 0.5 nanometers to about 100 microns. A material of the gate electrode 101 can be metal, alloy, heavily doped semiconductor (such as silicon), indium tin oxide (ITO), antimony tin oxide (ATO), conductive silver glue, conductive polymer or conductive carbon nanotubes. The metal or alloy material can be aluminum (Al), copper (Cu), tungsten (W), molybdenum (Mo), gold (Au), titanium (Ti), palladium (Ba) or any combination thereof. The material of the gate electrode 101 can be selected from high temperature resistant materials. In one embodiment, the gate electrode 101 is a palladium film with a thickness of about 50 nanometers.

The insulating layer 102 is located on a surface of the gate electrode 101. The insulating layer 102 is a continuous layered structure. The insulating layer 102 is used as a support layer. A material of the insulating layer 102 is an insulating material and can be hard materials or flexible materials. The hard materials can be glass, quartz, ceramics, diamond, or silicon wafers. The flexible materials can be plastics or resins. In one embodiment, the insulating layer 102 is made of high temperature resistant material. In one embodiment, the insulating layer 102 is a silicon wafer with a silicon dioxide layer.

The source electrode 103 and the drain electrode 104 are both made of conductive material. The conductive material can be selected from metal, ITO, ATO, conductive silver glue, conductive polymer, conductive carbon nanotube, and the like. The metal material can be aluminum (Al), copper (Cu), tungsten (W), molybdenum (Mo), gold (Au), titanium (Ti), palladium (Ba) or any combination thereof. In one embodiment, the source electrode 103 and the drain electrode 104 are made of high temperature resistant materials. The source electrode 103 and the drain electrode 104 can be a conductive film. In one embodiment, the source electrode 103 and the drain electrode 104 are respectively a metal titanium film, and a thickness of the metal titanium film is about 50 nanometers.

The single carbon nanotube 105 can be directly fixed on surfaces of the source electrode 103 and the drain electrode 104 by its own adhesiveness. In another embodiment, the single carbon nanotube 105 can also be fixed on the surfaces of the source electrode 103 and the drain electrode 104 by a conductive adhesive.

The single carbon nanotube 105 can be a single-wall carbon nanotube, a double-wall carbon nanotube or a multi-wall carbon nanotube. Various methods can be used to form defects in the middle portion 1053 of the single carbon nanotube 105. In one embodiment, a voltage can be applied to both ends of the carbon nanotubes 105 in a vacuum environment, and the carbon nanotubes 105 are energized to generate heat. Since the two ends of the carbon nanotubes 105 are directly in contact with external electrodes, and a heat generated by energizing both ends of the carbon nanotubes is dissipated through the external electrodes, so a temperature of the middle portion 1053 of the single carbon nanotube 105 is higher than that of the two ends. A carbon element on a wall of the middle portion 1053 is vaporized at a high temperature, and a seven-membered ring or an eight-membered ring of carbon atoms can be formed on the wall of the single carbon nanotube 105. Thus, a plurality of defects are formed on the wall of the single carbon nanotube 105. In one embodiment, defects can be formed by irradiating the middle portion 1053 of the single carbon nanotube 105 with laser or electromagnetic waves. In one embodiment, defects in the middle portion 1053 of the single carbon nanotube 105 are formed by the plasma etching method. In order to easily form defects in the middle portion 1053 of the single carbon nanotube 105, the single carbon nanotube 105 is preferably the single-wall carbon nanotube or the double-wall carbon nanotube. Since the multi-walled carbon nanotube comprises a large number of walls and a large number of conductive channels, it is relatively difficult to control a high temperature to produce defects in the multi-walled carbon nanotube instead of completely burnt. There are fewer conductive channels in the single-wall carbon nanotube or the double-wall carbon nanotube, so once defects are generated at the high temperature, it will directly affect the electrical properties of the single-wall carbon nanotube or the double-wall carbon nanotube.

Referring to FIG. 1, in one embodiment, the source electrode 103 and the drain electrode 104 are located on the surface of the insulating layer 102 and spaced apart from each other. The first end 1051 of the single carbon nanotube 105 is located on the surface of the source electrode 103, and the second end 1052 of the single carbon nanotube 105 is located on the surface of the drain electrode 104. That is, the source electrode 103 and the drain electrode 104 are located between the insulating layer 102 and the single carbon nanotube 105, and the single carbon nanotube 105 is suspended above the insulating layer 102 by the source electrode 103 and the drain electrode 104. In one embodiment, the source electrode 103 and the drain electrode 104 are directly in contact with the insulating layer 102 and the single carbon nanotube 105.

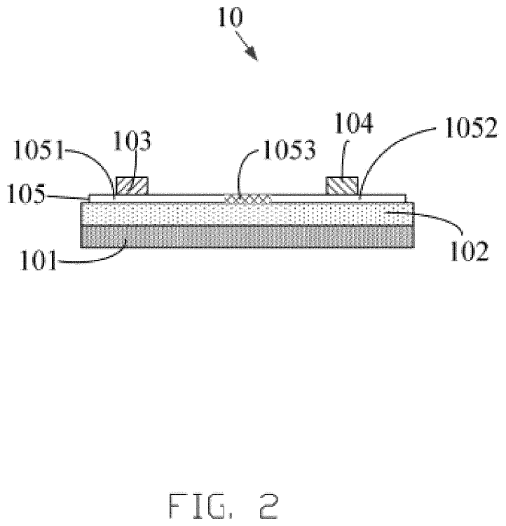

Referring to FIG. 2, in one embodiment, the single carbon nanotube 105 is directly in contact with the surface of the insulating layer 102. The source electrode 103 is located on the first end 1051 of the single carbon nanotube 105, and the drain electrode 104 is located on the second end 1052 of the single carbon nanotube 105. That is, the first end 1051 of the single carbon nanotube 105 is located between the insulating layer 102 and the source electrode 103, and the second end 1052 of the single carbon nanotube 105 is located between the insulating layer 102 and the drain electrode 104. The middle portion 1053 of the carbon nanotubes 105 can be suspended above the insulating layer 102 or supported by the insulating layer 102. In order to avoid the heat generated by the carbon nanotubes 105 from damaging the insulating layer 102 or transferring to the insulating layer 102 during operation, the middle portion 1053 of the single carbon nanotube 105 is preferably suspended.

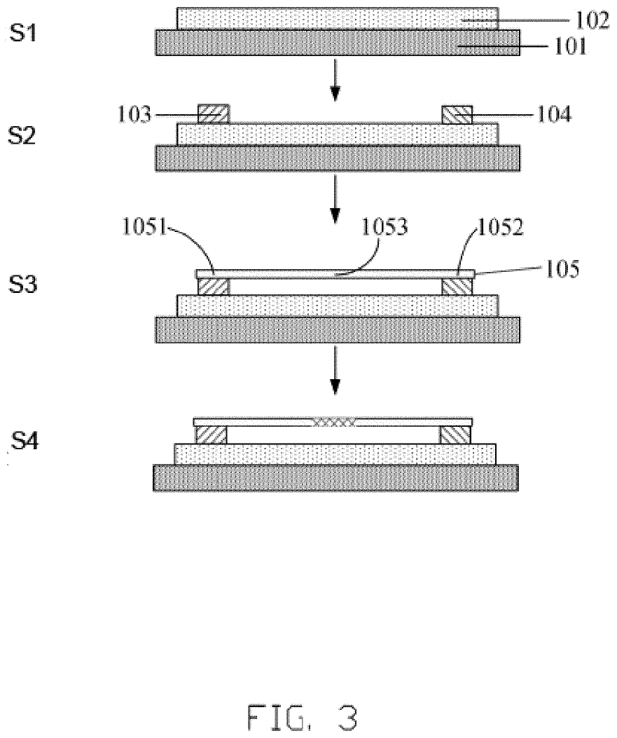

FIG. 3 illustrates a method of one embodiment of making the field effect transistor 10, the method comprises:

S1, providing a gate electrode 101, and forming an insulating layer 102 on a surface of the gate electrode 101;

S2, forming a source electrode 103 and a drain electrode 104 on a surface of the insulating layer 102 away from the gate electrode 101, wherein the source electrode 103 and the drain electrode 104 are spaced apart from each other;

S3, locating a single carbon nanotube 105 on the source electrode 103 and the drain electrode 104, wherein the single carbon nanotube 105 comprises a first end 1051, a second end 1052 opposite to the first end 1051, and a middle portion 1053 located between the first end 1051 and the second end 1051, the first end 1051 of the single carbon nanotube 105 is electrically connected to the source electrode 103, and the second end 1052 of the single carbon nanotube 105 is electrically connected to the drain electrode 104;

S4, forming a plurality of defects in the middle portion 1053 of the single carbon nanotube 105.

Before step S1, an insulating substrate can be provided, and then the gate electrode 101 can be formed on the insulating substrate. Methods for forming the gate electrode 101, the insulating layer 102, the source electrode 103, and the drain electrode 104 are not limited and can be formed by photolithography, magnetron sputtering, evaporation, and the like.

In step S3, the single carbon nanotube 105 can be prepared by a chemical vapor deposition method or a physical vapor deposition method. In one embodiment, according to the “kite flying mechanism”, the chemical vapor deposition method is used to grow an ultra-long carbon nanotube. The method of growing the ultra-long carbon nanotube comprises the following substeps: (a) a growth substrate and a receiving substrate are provided, and a monodisperse catalyst is formed on a surface of the growth substrate; (b) a carbon source gas is introduced; (c) the nanotubes grow and float in a direction of airflow, and finally fall on a surface of the receiving substrate. About a growth method of the ultra-long carbon nanotube, please refer to the Chinese Patent Application No. 200810066048.7 filed by Shoushan Fan et al. on Feb. 1, 2008. In order to save space, a detailed description is omitted here, but all the technical disclosures of the above-mentioned application should also be regarded as part of the technical disclosure of the present invention.

In one embodiment, after the single carbon nanotube 105 is prepared, the single carbon nanotube 105 can be directly transferred to surfaces of a source electrode 103 and a drain electrode 104. In another embodiment, when the single carbon nanotube 105 is a double-wall carbon nanotube or a multi-wall carbon nanotube, an outer wall of the single carbon nanotube 105 can be removed first to obtain an inner layer of the single carbon nanotube 105, and then the inner layer of the single carbon nanotube 105 is transferred to the surfaces of the source electrode 103 and the drain electrode 104. The inner layer of the single carbon nanotube 105 is super clean, which is conducive to adhesion of the single carbon nanotube 105 to the source electrode 103 and the drain electrode 104.

The method for locating the single carbon nanotube 105 on the source electrode 103 and the drain electrode 104 is not limited. In one embodiment, the method for transferring the single carbon nanotube 105 comprises the following steps:

Step 31, making the single carbon nanotube 105 to be observed under an optical microscope;

Step 32, providing two tungsten needle tips, and clipping the single carbon nanotube 105 with the two tungsten needle tips;

Step 33, transferring the single carbon nanotube 105 to a target position via the two tungsten needle tips.

In step 31, since a diameter of the single carbon nanotube 105 is only a few nanometers or tens of nanometers, the single carbon nanotube 105 cannot be observed under an optical microscope, but can only be observed under a scanning electron microscope, a transmission electron microscope, etc. In order to observe the single carbon nanotube 105 under the optical microscope, a plurality of nanoparticles are formed on a surface of the single carbon nanotube 105. The plurality of nanoparticles can scatter light. Thus, the single carbon nanotube 105 with nanoparticles can be observed under the optical microscope. The material of the plurality of nanoparticles is not limited. The plurality of nanoparticles can be titanium dioxide (TiO₂) nanoparticles, sulfur (S) nanoparticles, and the like.

In step 32, two tungsten needle tips are provided. Under the optical microscope, one of the two tungsten needle tips lightly touches one end of the single carbon nanotube 105, and the single carbon nanotube 105 will gently adhere to the tungsten needle tip under a van der

Waals force. The single carbon nanotube 105 is gently dragged by the tungsten needle tip, and the outer wall of the single carbon nanotube 105 is broken under an external force. Since the inner layer and the outer wall of the single carbon nanotube 105 are super lubricated, the inner layer of the single carbon nanotube 105 can be extracted from the single carbon nanotube 105. Since the plurality of nanoparticles are coated on the outer wall of the single carbon nanotube 105, a position of the inner layer can be roughly inferred. When the inner layer is extracted to a required length, another tungsten needle is used to cut the other end of the single carbon nanotube 105. Thus, the single carbon nanotube 105 is transferred and adsorbed between the two tungsten needle tips.

In step 33, under the optical microscope, the two tungsten needle tips are gently moved, the carbon nanotube 105 is moved with a movement of the two tungsten needle tips. One end of the single carbon nanotube 105 is located on the surface of the source electrode 103 and is directly in contact with the source electrode 103. The other end of the single carbon nanotube 105 is located on the surface of the drain electrode 104 and is directly in contact with the drain electrode 104.

The order of step 2 and step 3 can be reversed. That is, the single carbon nanotube 105 can be transferred to the surface of the insulating layer 102 first, so that the single carbon nanotube 105 is directly in contact with the insulating layer 102. The source electrode 103 is located on the first end 1051, and the drain electrode 104 is located on the second end 1052.

In step 4, the method of forming defects in the middle portion 1053 of the single carbon nanotube 105 is not limited. Specifically, the method can be applying a voltage to both ends of the single carbon nanotube 105, irradiating the middle portion 1053 of the single carbon nanotube 105 with laser or electromagnetic waves, etching the middle portion 1053 of the single carbon nanotube 105 with plasma, and so on. In the above method, parameters, such as a value of an applied voltage, a time of applying the voltage, a laser power, a time of laser irradiation, etc., are not determined. The parameters are related to the diameter, length, number of walls of the single carbon nanotube 105 that need to form defects. In one embodiment, when the single carbon nanotube 105 is the single-walled carbon nanotubes, the value of the applied voltage can be 1.5V-2.5V, and when the single carbon nanotube 105 is the double-walled carbon nanotube, the value of the applied voltage can be 2V-3V.

In one embodiment, the method for forming defects in the middle portion 1053 of the carbon nanotube comprises: applying a bias voltage to the source electrode 103 and the drain electrode 104, and after applying the bias voltage for a period of time, stop applying the bias voltage.

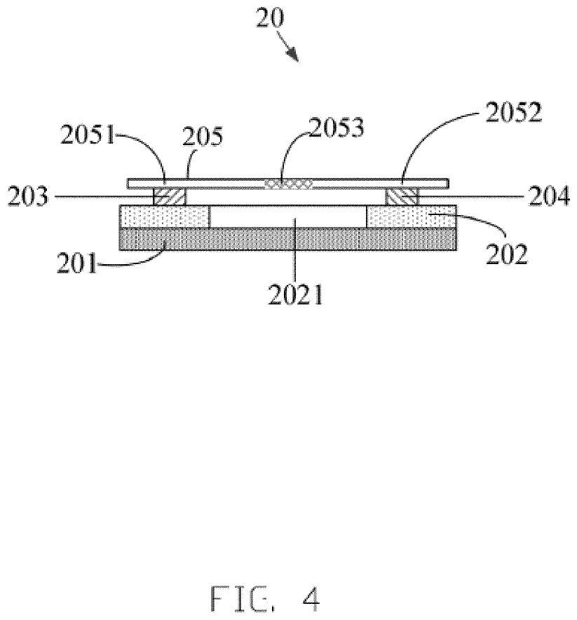

Referring to FIG. 4, a field effect transistor 20 is provided in the second embodiment. The field effect transistor 20 comprises a gate electrode 201, an insulating layer 201, a first electrode 203, and a drain electrode 204 and a single carbon nanotube 205. The structure of the field effect transistor 20 is basically the same as the field effect transistor 10.

The difference is that the insulating layer 202 has a hole 202 in the field effect transistor 20. The hole 2021 can be a through hole or a blind hole. The through hole penetrates the insulating layer 202 along the thickness direction of the insulating layer 202.

In one embodiment, referring to FIG. 4, the first electrode 203 and the drain electrode 204 are respectively located on both sides of the hole 2021 of the insulating layer 202.

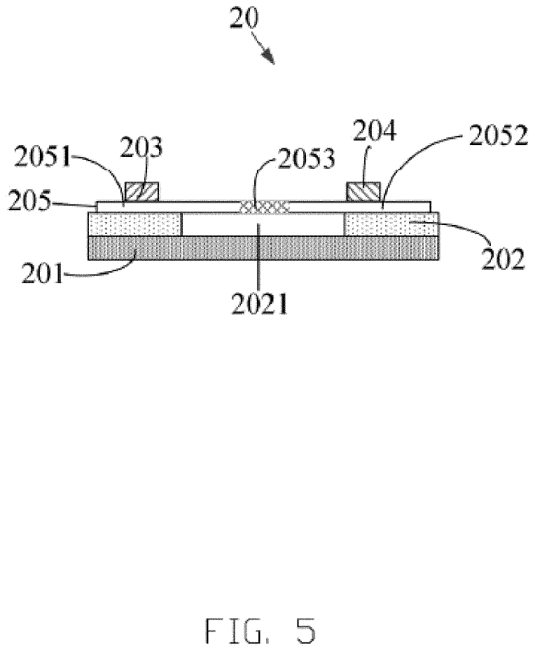

The first end 2051 of the carbon nanotube 205 is located on a surface of the first electrode 203, and the second end 2052 of the carbon nanotube 205 is located on a surface of the drain electrode 204. The middle portion 2053 of the carbon nanotube 205 is suspended above the hole 2021 of the insulating layer 202. In another embodiment, referring to FIG. 5, the carbon nanotube 205 is directly in contact with the insulating layer 202, the two ends of the carbon nanotube 205 are respectively located on both sides of the hole 2021, and the middle portion 2053 of the carbon nanotube 205 is suspended above the hole 2021. The first end 2051 of the carbon nanotube 205 is located between the insulating layer 202 and the first electrode 203, and the second end 2052 of the carbon nanotube 205 is located between the insulating layer 202 and the drain electrode 204.

The materials of the gate electrode 201, the insulating layer 202, the first electrode 203, and the drain electrode 204 are respectively the same as those of the gate electrode 101, the insulating layer 102, the source electrode 103 and the drain electrode 104.

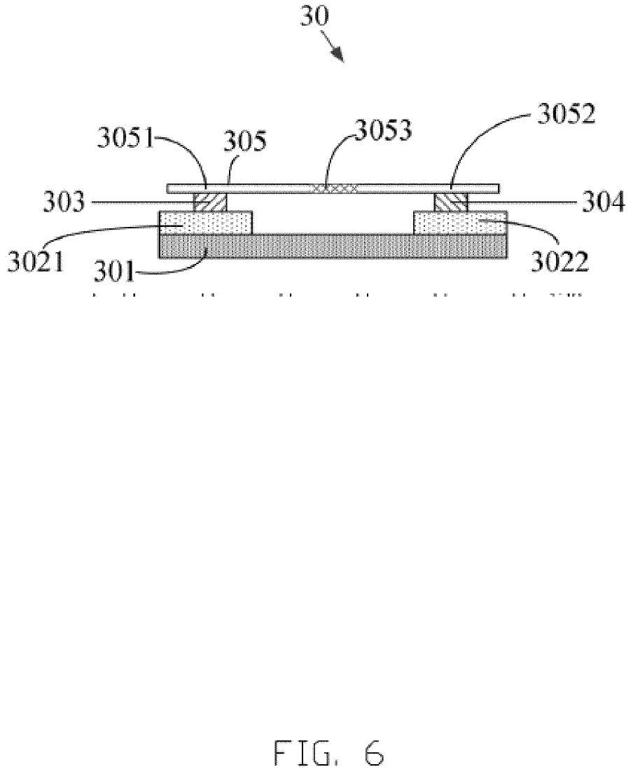

Referring to FIG. 6, a field effect transistor 30 is provided in the third embodiment. The field effect transistor 30 comprises a gate electrode 301, an insulating layer 302, a first electrode 303, and a drain electrode 304 and a single carbon nanotube 305. The structure of the field effect transistor 30 is basically the same as the field effect transistor 20. The difference is that the insulating layer 302 comprises a first insulating layer 3021 and a second insulating layer 3022, and the first insulating layer 3021 and the second insulating layer 3022 are spaced apart from each other and located on a surface of the gate electrode 301.

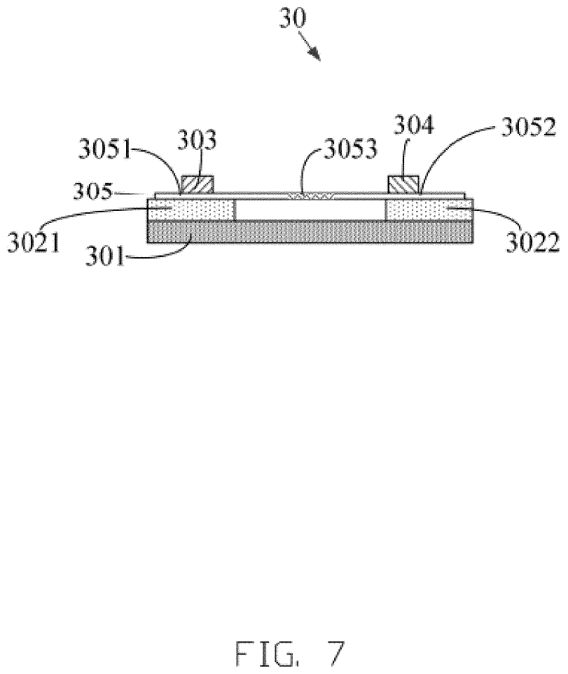

In one embodiment, referring to FIG. 6, the first electrode 303 is located on a surface of the first insulating layer 3021, and the drain electrode 304 is located on a surface of the second insulating layer 3022. The first end 3051 of the carbon nanotube 305 is located on a surface of the first electrode 303, the second end 3051 of the carbon nanotube 305 is located on a surface of the drain electrode 304, and the middle portion 3053 of the carbon nanotube 305 is suspended. In another embodiment, referring to FIG. 7, the first end 3051 of the carbon nanotube 305 is located between and directly in contact with the first insulating layer 3021 and the first electrode 303. The second end 3052 of the carbon nanotube 305 is located between and directly in contact with the second insulating layer 3022 and the drain electrode 304. The middle portion 3053 of the carbon nanotube 305 is suspended.

The materials of the gate electrode 301, the insulating layer 302, the first electrode 303, and the drain electrode 304 are respectively the same as those of the gate electrode 101, the insulating layer 102, the source electrode 103 and the drain electrode 104.

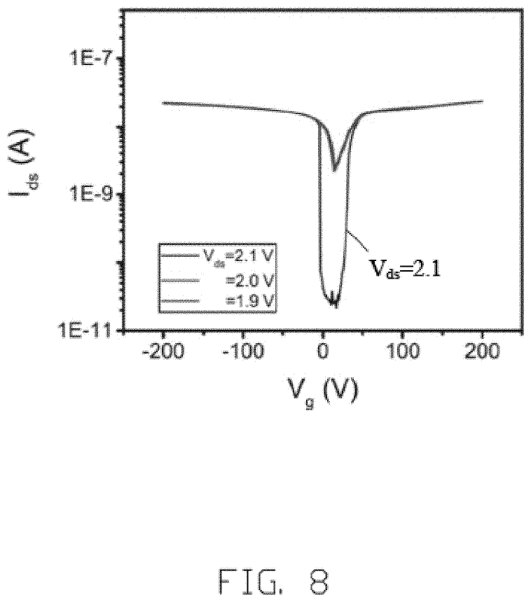

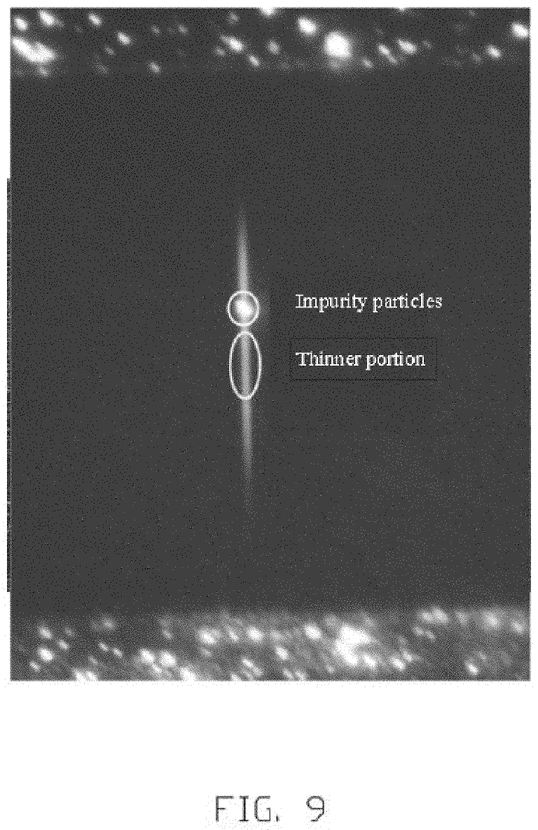

The following test experiments all use the field effect transistor 30. Referring to FIG. 8, a bias voltage is set at both ends of a single carbon nanotube 105 to 1.9 V and 2.0 V. The single carbon nanotube 105 is an intact carbon nanotube without defects. The single carbon nanotube 105 is heated to generate a high temperature, but at this time, an on-off ratio of the carbon nanotube is only 10. The bias voltage set at both ends of the single carbon nanotube 105 is further increased to 2.1 V, the single carbon nanotube 105 is in a completely off state when the gate electrode voltage is close to 0 V, and the on-off ratio is increased to about 10³. This is because the middle portion of the single carbon nanotube 105 is self-heating to produce defects when the bias voltage is 2.1 V, which causes the on-off ratio of the single carbon nanotube 105 to suddenly increase. Referring to FIG. 9 is a Rayleigh photo of the carbon nanotube when the bias voltage is 2.1 V. As shown in FIG. 9, the middle portion of the single carbon nanotube 105 becomes thinner and a Rayleigh scattering in the middle portion becomes weaker, indicating that defects are formed in the middle portion of the single carbon nanotube 105.

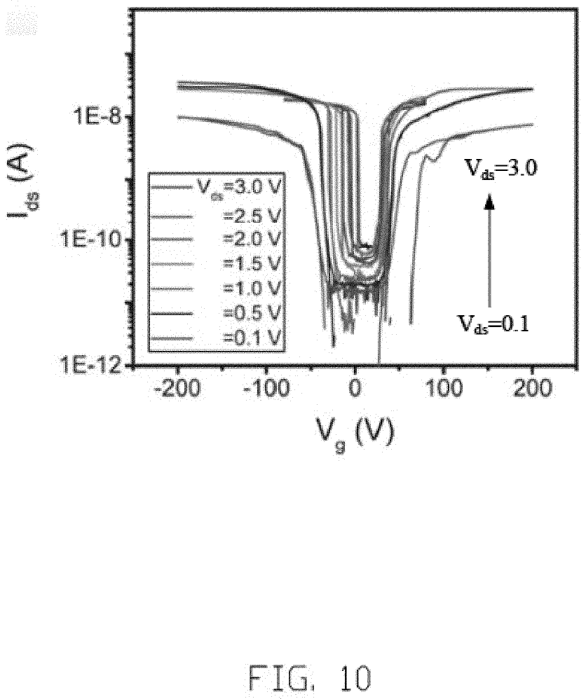

After defects are formed in the middle portion of the single carbon nanotube 105, the bias voltage at both ends of the single carbon nanotube 105 is reduced. As shown in FIG. 10, the single carbon nanotube 105 is all in a completely off state from a low bias voltage of 0.1 V to a high bias voltage of 3.0 V, indicating that the middle portion of the single carbon nanotube 105 with defects has a high on-off ratio at a high temperature.

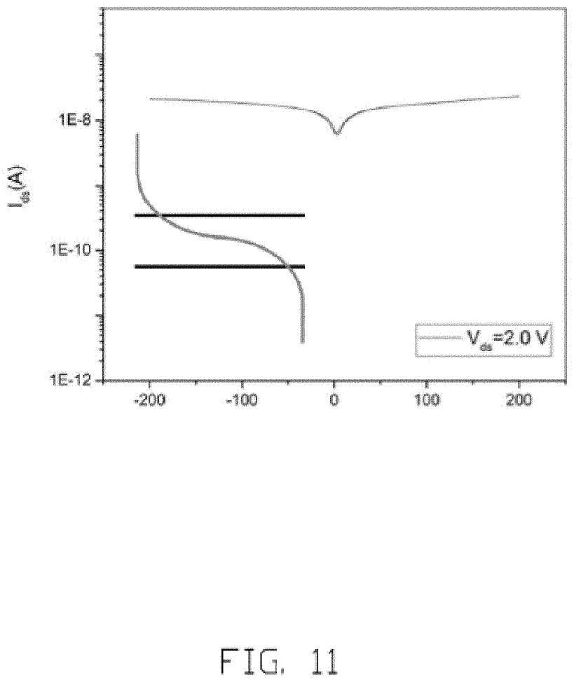

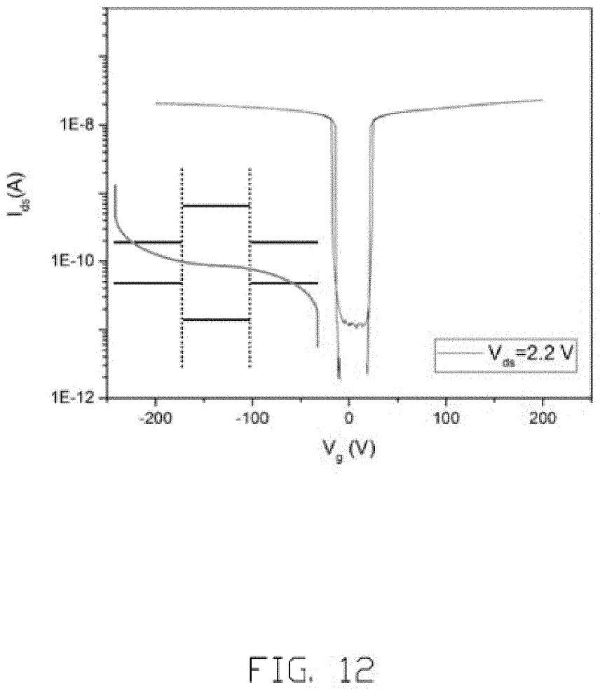

Referring to FIG. 11, when the bias voltage is 2.0 V, the single carbon nanotube 105 cannot be turned off due to an electron distribution on a conduction band. Referring to FIG. 12, when the bias voltage is increased to 2.2 V, the middle portion of the single carbon nanotube 105 has a large number of defects due to the high temperature, which causes a band gap of the middle portion of the single carbon nanotube 105 to increase. A temperature of the two ends of the single carbon nanotube 105 is not high, thus, a band gap of the two ends of the single carbon nanotube 105 has no change. Therefore, the single carbon nanotube 105 has a large band gap on the middle portion and small band gaps on both ends.

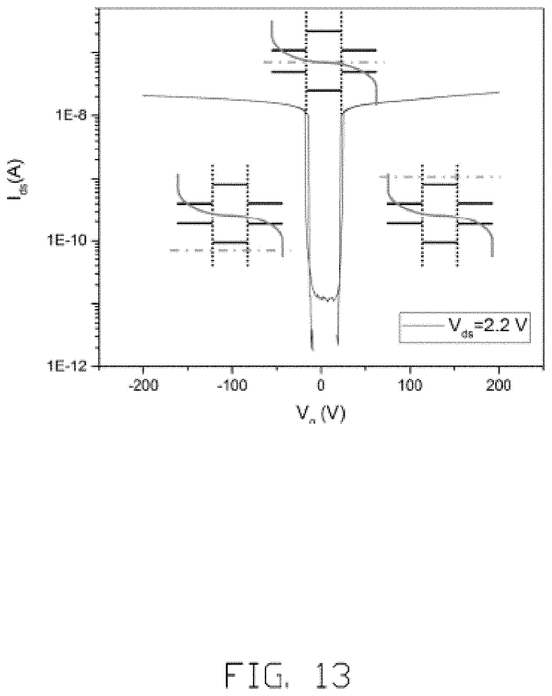

Referring to FIG. 13, when a gate electrode voltage is negative, a Fermi surface is located on a valence band of the single carbon nanotube 105, so the single carbon nanotube 105 is in an on state; when the gate electrode voltage is close to 0V, the Fermi surface is in the middle of a band gap. There are a large number of defects in the single carbon nanotube 105, and the band gap is greatly increased, so only a few electrons are distributed on the conduction band, and the conductivity is poor. Therefore, the single carbon nanotube 105 is completely turned off. When the gate electrode voltage is positive, the Fermi surface is located on the conduction band of the single carbon nanotube 105, so the single carbon nanotube 105 is in the on state again and become completely conductive.

Four single carbon nanotubes 105 are selected to prepare four field-effect transistors as described in the third embodiment, and defects are respectively formed in the middle portions of the four single carbon nanotubes 105. The four field-effect transistors are respectively numbered 1-4. The on-off ratio of the four field effect transistors is measured at high temperature, and the results are shown in the following table 1.

TABLE 1

| Sample number | Maximum temperature (K) | On/off Ratio |
|---|---|---|
| 1 | ~1700 | >10³ |
| 2 | ~1900 | >10² |
| 3 | ~1700 | >10² |
| 4 | ~1600 | >10³ |

As shown in Table 1, a maximum operating temperature of the four field effect transistors can reach 1900 K, and the On-off ratio can be greater than 10³.

Even though numerous characteristics and advantages of certain inventive embodiments have been set out in the foregoing description, together with details of the structures and functions of the embodiments, the disclosure is illustrative only. Changes can be made in detail, especially in matters of an arrangement of parts, within the principles of the present disclosure to the full extent indicated by the broad general meaning of the terms in which the appended claims are expressed.

Depending on the embodiment, certain of the steps of methods described can be removed, others can be added, and the sequence of steps can be altered. It is also to be understood that the description and the claims drawn to a method can comprise some indication in reference to certain steps. However, the indication used is only to be viewed for identification purposes and not as a suggestion as to an order for the steps.

The embodiments shown and described above are only examples. Even though numerous characteristics and advantages of the present technology have been set forth in the foregoing description, together with details of the structure and function of the present disclosure, the disclosure is illustrative only, and changes can be made in the detail, especially in matters of shape, size and arrangement of the parts within the principles of the present disclosure up to, and including the full extent established by the broad general meaning of the terms used in the claims. It will, therefore, be appreciated that the embodiments described above can be modified within the scope of the claims.

What is claimed is:

1. A field effect transistor comprising:
an insulating layer comprising a first surface and a second surface opposite to the first surface;
a gate electrode located on the first surface of the insulating layer;
a source electrode and a drain electrode located on the second surface of the insulating layer and spaced away from each other; and
a single carbon nanotube comprising a first end, a second end opposite with the first end, and a middle portion located between the first end and the second end; wherein the first end of the single carbon nanotube is electrically connected with the source electrode, the second end of the single carbon nanotube is electrically connected with the drain electrode, the single carbon nanotube is suspend above the insulating layer, and the middle portion of the single carbon nanotube comprises a plurality of defects.

2. The field effect transistor of claim 1, wherein the middle portion of the single carbon nanotube comprises a seven-membered ring or an eight-membered ring.

3. The field effect transistor of claim 1, wherein the single carbon nanotube is a single-wall carbon nanotube or a double-wall carbon nanotube.

4. The field effect transistor of claim 1, wherein the insulating layer comprises a through hole or a blind hole.

5. The field effect transistor of claim 4, wherein the source electrode and the drain electrode are respectively located on both sides of the hole of the insulating layer.

6. The field effect transistor of claim 1, wherein the insulating layer comprises a first insulating layer and a second insulating layer, and the first insulating layer and the second insulating layer are spaced apart from each other and located on a surface of the gate electrode.

7. The field effect transistor of claim 6, wherein the source electrode is located on a surface of the first insulating layer, and the drain electrode is located on a surface of the second insulating layer.

8. The field effect transistor of claim 1, wherein the single carbon nanotube is formed by removing an outer wall of a double-wall carbon nanotube or a multi-wall carbon nanotube.

9. A field effect transistor comprising:
an insulating layer comprising a first surface and a second surface opposite to the first surface;
a gate electrode located on the first surface of the insulating layer;
a single carbon nanotube located on the second surface of the insulating layer and comprising a first end, a second end opposite to the first end, and a middle portion located between the first end and the second end, wherein the middle portion of the single carbon nanotube comprises a plurality of defects; and
a source electrode and a drain electrode, wherein the first electrode is located on and electrically connected to the first end of the single carbon nanotube, and the second electrode is located on and electrically connected to the second end of the single carbon nanotube.

10. The field effect transistor of claim 9, wherein the middle portion of the single carbon nanotube comprises a seven-membered ring or an eight-membered ring.

11. The field effect transistor of claim 9, wherein the single carbon nanotube is a single-wall carbon nanotube or a double-wall carbon nanotube.

12. The field effect transistor of claim 9, wherein the insulating layer comprises a through hole or a blind hole.

13. The field effect transistor of claim 9, wherein the insulating layer comprises a first insulating layer and a second insulating layer, and the first insulating layer and the second insulating layer are spaced apart from each other.

14. The field effect transistor of claim 9, wherein the single carbon nanotube is formed by removing an outer wall of a double-wall carbon nanotube or a multi-wall carbon nanotube.
